(19) United States
(12) Patent Application Publication
(10) Pub. No.: US 2010/0134995 A1
(43) Pub. Date: Jun. 3, 2010

(54) Electrical Interconnection System

(75) Inventor: Julie N. Strickland, McKinney, TX (US)

Correspondence Address: BAKER BOTTS LLP, 2001 ROSS AVENUE, 6TH FLOOR, DALLAS, TX, 75201-2980, US

(73) Assignee: Raytheon Company, Waltham, MA (US)

(21) Appl. No.: 12/628,805

(22) Filed: Dec. 1, 2009

Related U.S. Application Data
(60) Provisional application No. 61/119,290, filed on Dec. 2, 2008.

(51) Int. Cl. H05K 1/11

(52) U.S. Cl. 361/792

(57) ABSTRACT

According to one embodiment, an electrical interconnection system includes a pair of printed wiring boards formed of a printed wiring board material. Each printed wiring board has multiple surface pads formed on a surface of the printed wiring board adjacent its outer edge. The surface of each printed wiring board is operable to be placed adjacent to one another such that an electrical circuit coupled to one printed wiring board is electrically coupled to another electrical circuit of the other printed wiring board by contact of the surface pads of each printed wiring board with one another.

### RELATED APPLICATIONS

This application claims priority to U.S. Provisional Patent Application Ser. No. 61/119,290, entitled “ELECTRICAL INTERCONNECTION SYSTEM,” which was filed on Dec. 2, 2008. U.S. Provisional Patent Application Ser. No. 61/119,290 is hereby incorporated by reference.

### TECHNICAL FIELD OF THE DISCLOSURE

This disclosure generally relates to electrical devices, and more particularly, to an electrical interconnection system that may be used to couple electrical circuits to one another.

### BACKGROUND OF THE DISCLOSURE

Complex electrical systems are often designed to have multiple subsystems that are electrically coupled together to perform some useful function. Each subsystem usually performs a portion of the overall functionality of its electrical system. The design of electrical systems with multiple subsystems may allow designers to accommodate these electrical systems in various types of enclosures. Multiple subsystems may also provide an efficient approach for periodic upgrading of the various functional elements of the electrical system without affecting other portions of the electrical system.

### SUMMARY OF THE DISCLOSURE

According to one embodiment, an electrical interconnection system includes a pair of printed wiring boards formed of a printed wiring board material. Each printed wiring board has multiple surface pads formed on a surface of the printed wiring board adjacent its outer edge. The surface of each printed wiring board is operable to be placed adjacent to one another such that an electrical circuit coupled to one printed wiring board is electrically coupled to another electrical circuit of the other printed wiring board by contact of the surface pads of each printed wiring board with one another.

Some embodiments of the disclosure may provide numerous technical advantages. For example, one embodiment of the electrical interconnection system may provide denser packaging of electrical systems comprising multiple subsystems. Known implementations of connectors are relatively large in size and may be cumbersome to work with when physically coupled to printed wiring boards or flex circuits. The electrical interconnection system according to certain embodiments of the present disclosure may be relatively compact such that subsystems may be interconnected with relatively lower profiles than typically provided by known electrical connectors.

Some embodiments may benefit from some, none, or all of these advantages. Other technical advantages may be readily ascertained by one of ordinary skill in the art.

### BRIEF DESCRIPTION OF THE DRAWINGS

A more complete understanding of embodiments of the disclosure will be apparent from the detailed description taken in conjunction with the accompanying drawings in which:

FIGS. 1A and 1B show a cross-sectional, side view and a top view, respectively, of one embodiment of an electrical interconnection system according to the teachings of the present disclosure;

FIGS. 2A and 2B show a plan view and an enlarged, partial, elevational view, respectively, of another embodiment of the electrical interconnection system according to the teachings of the present disclosure; and

FIGS. 3A and 3B show a plan view and an enlarge, partial, elevational view, respectively, of another embodiment of the electrical interconnection system according to the teachings of the present disclosure.

### DETAILED DESCRIPTION OF EXAMPLE EMBODIMENTS

It should be understood at the outset that, although example implementations of embodiments are illustrated below, various embodiments may be implemented using any number of techniques, whether currently known or not. The present disclosure should in no way be limited to the example implementations, drawings, and techniques illustrated below. Additionally, the drawings are not necessarily drawn to scale.

Complex electrical systems are often configured with multiple subsystems that function together to perform a useful function. These subsystems are usually coupled together using electrical interconnection systems that electrically couple certain nodes of one subsystem to those of another. Interconnection of electrical circuits to one another is usually provided by complementary connectors configured on multiple electrical circuits. Conventional connectors typically have a generally rigid structure, which may present various design problems when used in conjunction with electrical circuits, such as flex circuits having a profile or thickness that is typically less than the profile of its associated connector. For example, as a result of using such conventional bulky connectors, special designs may need to be created which in turn can consume a relatively large amount of volume. With such difficulties, certain embodiments recognize that an electrical interconnection system may be implemented requiring relatively less space than conventional connectors and may be coupled and/or separated in a relatively quick manner.

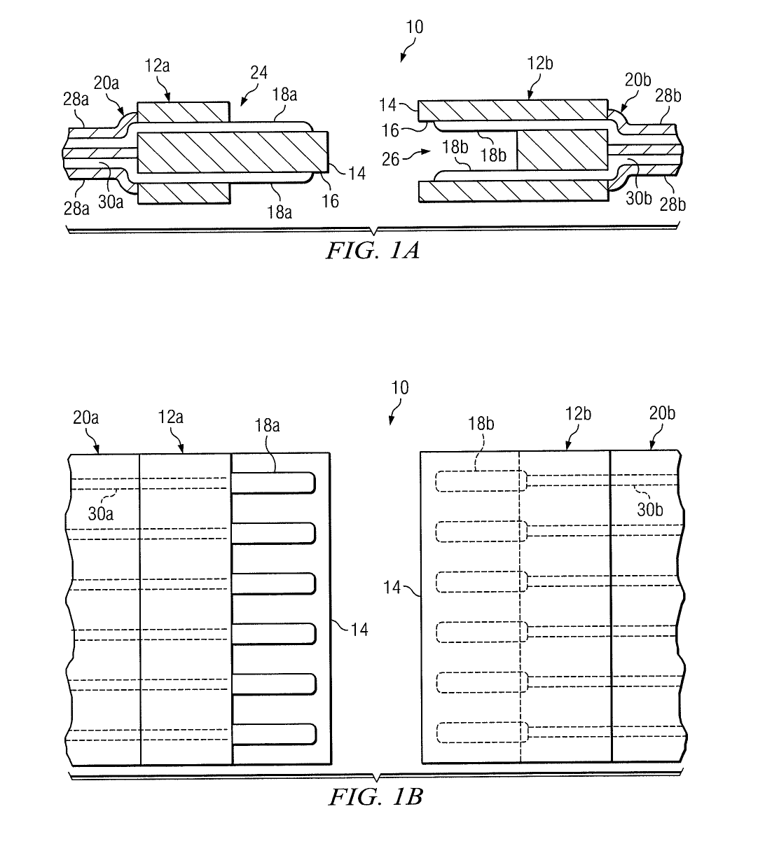

FIGS. 1A and 1B show a cross-sectional, side view and a top view, respectively, of one embodiment of an electrical interconnection system 10 according to the teachings of the present disclosure. Electrical interconnection system 10 includes a pair of printed wiring boards 12a and 12b that each have an outer edge 14 and a surface 16 adjacent to its outer edge 14. The surface 16 of each printed wiring board 12a and 12b is configured with multiple surface pads 18a and 18b. Printed wiring boards 12a and 12b are configured with corresponding electrical circuits 20a and 20b, which in this particular embodiment are flex circuits, such that electrical circuits 20a and 20b may be alternatively coupled or decoupled from one another by placing surfaces 16 of each printed wiring board 12a and 12b adjacent one another.

In the particular embodiment shown, the surface 16 of printed wiring board 12a forms a portion of a tab 24 while the surface 16 of printed wiring board 12b forms a portion of a slot 26. Tab 24 and slot 26 are dimensioned such that tab 24 may be inserted into slot 26 with a press-in type fit. In other embodiments, multiple tabs may be formed in printed wiring board 12a for insertion or removal from multiple slots formed in printed wiring board 12b.

Printed wiring boards 12a and 12b may be formed of any rigid or flexible printed wiring board material, such as a fiber reinforced resin material that has a structure for placement of surface pads 18a and 18b and conductors 30a and 30b. Examples of suitable types of printed wiring board materials may include flame resistant 4 (FR4) material, woven quartz, resin impregnated cellulose paper, or resin reinforced chopped felt. The printed wiring boards 12a and 12b provide sufficient structural integrity for insertion and removal of tab 24 from slot 26.

Electrical circuits 12a and 12b may be any generally flexible or rigid structure that is configured to carry electrical current. In the particular embodiment shown, electrical circuits 12a and 12b comprise flex circuits that each includes one or more flexible layers 28a and 28b made of flexible insulative material on which conductors 30a and 30b are placed. The flexible, insulative material of this type may include a polyimide material, such as Kapton™ material manufactured by DuPont Corporation, located in Wilmington, Del.

Certain embodiments using printed wiring boards 12a and 12b formed of printed wiring board material may provide an advantage when manufactured with electrical circuits 20a and 20b. Manufacture of electrical circuits 20a and 20b typically uses a layering process in which several layers of flexible material, such as polyimide material are formed with one or more conductors 30a and 30b, such as copper traces. During this manufacturing process, additional layers of similar or differing materials may be applied at one end to form printed wiring boards 12a and 12b. Thus, electrical interconnection to electrical circuits 20a and 20b may be accomplished without bulky electrical connectors that may be cumbersome to use, expensive, and prone to damage.

Surface pads 18a and 18b configured on tab 24 and slot 26 are electrically coupled to conductors 30a and 30b of electrical circuits 20a and 20b, respectively. Surface pads 18a and 18b are made of a conductive material, such as copper and may be formed on tab 24 and slot 26 using any suitable process, such as those processes used for manufacturing copper traces on printed wiring board materials. Tab 24 has a dimensional size that allows for insertion into slot 26. When inserted, surface pads 18a on tab 24 form an electrical connection with surface pads 18b on slot 26 such that conductors 30a are electrically coupled with conductors 30b.

In one embodiment, surface pads 18a and 18b are integrally formed with conductors 30a and 30b using an etching process commonly associated with the manufacture of electrical printed wiring boards. In another embodiment, surface pads 18a and/or 18b may have a resilience for providing a spring-like force against their corresponding surface pads 18b and/or 18a when printed wiring boards 12a and 12b are mated together. This resilience characteristic may be imparted in any suitable manner. For example, conductive metal strips may be soldered onto the surface of surface pads 18a and/or 18b. These metal strips may have an unattached end that project outwards from surfaces 16 of either printed wiring board 12a or 12b such that, when its complementary printed wiring board 12b or 12a is inserted, metal strips are bent away from their resting shape in order to apply physical pressure on its associated surface pad 18a or 18b.

Although the present embodiment describes printed wiring boards 12a and 12b coupled to electrical circuits 20a and 20b comprising flex circuits, they may be coupled to any suitable type of electrical circuit for which electrical interconnection may be desired. For example, some embodiments of printed wiring boards 12a and 12b may be coupled to electrical circuits including, but not limited to, printed wiring boards (PWBs), electrical circuits, flex rigid circuits, rigid circuits, circuit card assemblies (CCAs), cable bundles, multiple discrete wires, and/or any combination thereof. For example, either printed wiring board 12a or 12b may be integrally formed with an electrical circuit comprising a generally rigid or flexible printed wiring board such that printed wiring board 12a or 12b and its associated electrical circuit are made one continuous piece. As another example, either printed wiring board 12a or 12b may be electrically coupled to an electrical circuit that may be, for example, a cable bundle or multiple elongated wires that terminate at printed wiring board 12a or 12b.

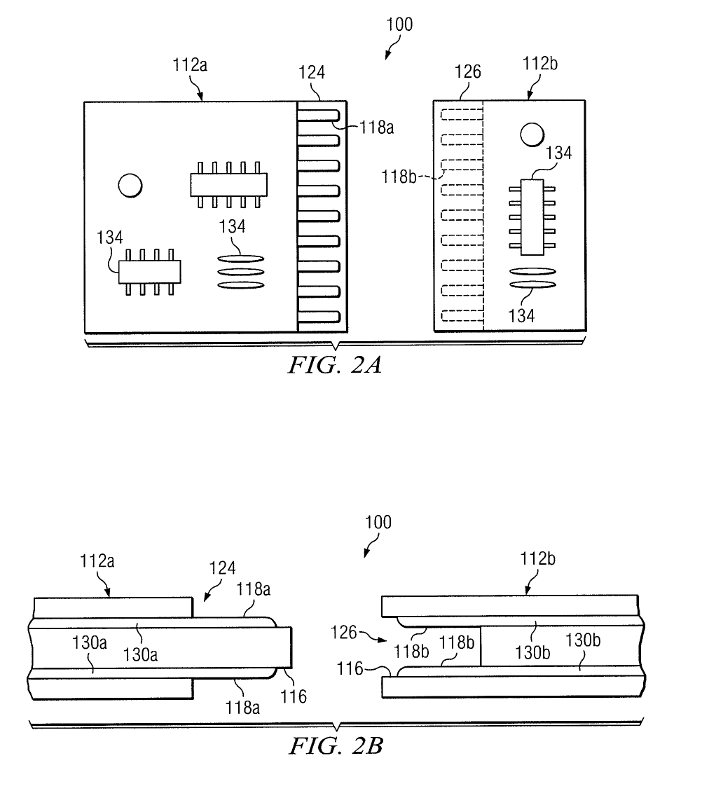

FIGS. 2A and 2B show a plan view and an enlarged, partial view, respectively, of another embodiment of the electrical interconnection system 100 according to the teachings of the present disclosure. Electrical interconnection system 100 includes a pair of printed wiring boards 112a and 112b, each having surfaces 116 formed on a portion of a tab 124 and a slot 126, respectively, and configured with multiple surface pads 118a and 118b and conductors 130a and 130b that are similar in design and function to those of electrical interconnection system 10 of FIGS. 1A and 1B. Electrical interconnection system 100 differs, however, in that printed wiring boards 112a and 112b each comprise one or more electrical components 134.

Electrical components 134 configured on either printed wiring board 112a or 112b may be any suitable type of electrical circuit. For example, electrical components 134 on printed wiring board 112a may be a motherboard while electrical components 134 on printed wiring board 112b may be a daughter card that performs a certain sub-task of the functionality provided by its motherboard. In this case, the elements of electrical interconnection system 100 is integrally formed during manufacture of printed wiring boards 112a and 112b such that electrical interconnection of daughter card to its associated motherboard may not require additional connectors. Thus, certain embodiments of electrical interconnection system 100 may provide enhanced utility by reducing complexity and assembly costs associated with ancillary connectors mounted to printed wiring boards 112a and 112b.

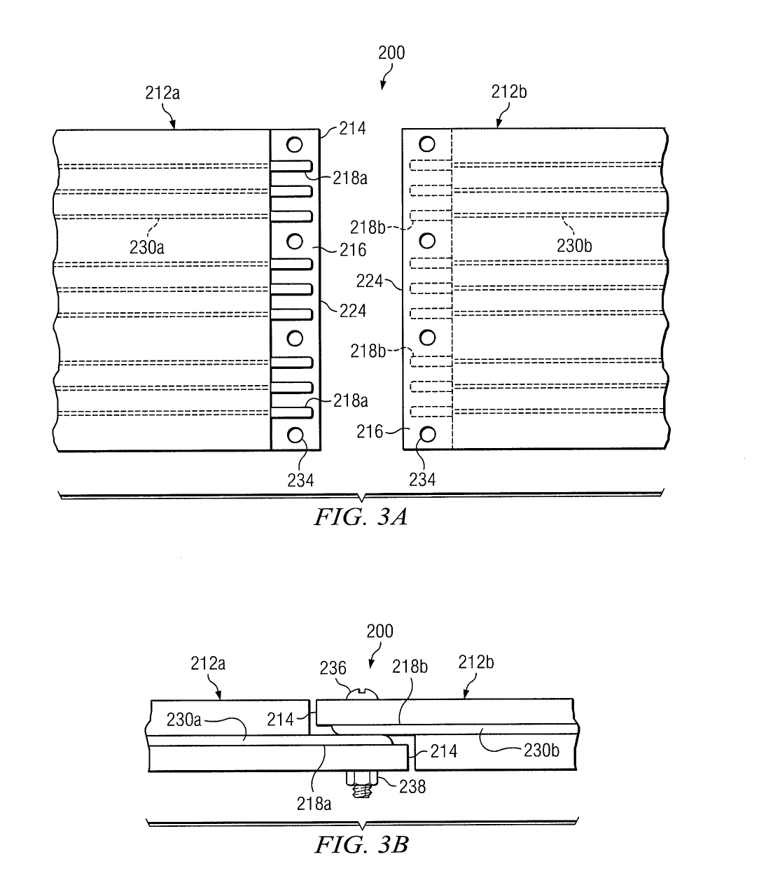

FIGS. 3A and 3B show a plan view and a partial, enlarged elevational view, respectively, of another embodiment of the electrical interconnection system 200 according to the teachings of the present disclosure. Electrical interconnection system 200 includes a pair of printed wiring boards 212a and 212b, each having surfaces 216 formed on a portion of a tab 224, and configured with multiple surface pads 218a and 218b and conductors 230a and 230b that are similar in design and function to those of electrical interconnection system 10 of FIGS. 1A and 1B. Electrical interconnection system 200 differs, however, in that surfaces 216 are formed on tabs 224 configured on both printed wiring boards 212a and 212b.

In the particular embodiment shown, tabs 224 are created in both printed wiring boards 212a and 212b by forming notches in their outer edges 214. Tabs 224 may be formed in any suitable manner. In one embodiment, tabs 224 may be formed by a machining process in which material is removed by grinding or ablating a portion of printed wiring boards 212a and 212b. In another embodiment, tabs 224 may be formed during manufacture of printed wiring boards 212a and 212b in which tabs 224 are formed by a layering process that leaves tabs 224 relatively narrower than the other portion of printed wiring boards 212a and 212b. Using this process, once sufficient layers are deposited to form tabs 224, a solid layer of copper may be applied and subsequently etched to form surface pads 218a and 218b and their associated conductors 230a and 230b.

Electrical interconnection system 200 may also include multiple holes 234 fashioned at regular intervals across each surface 216. Fasteners, such as bolts 236 may be inserted through holes 234 and secured using their associated nuts 238 for holding printed wiring board 212a to printed wiring board 212b. In other embodiments, other types of fasteners, such as rivets or adhesives may be used to hold printed wiring boards together. In a likewise manner, the embodiments as described with reference to FIGS. 1A through 2B may also be implemented with fasteners for holding printed wiring board 12a or 112a to printed wiring board 12b or 112b, respectively. In other embodiments, one or more interconnect systems may be implemented that apply a spring force to ensure electrical contact between printed wiring board 212a and printed wiring board 212b in a fixed relation to one another. For example, interconnects, such as those made by Neoconix™, Samtec™, or Cinch™, may be formed of a resilient material that resists a deformed shape when applied over printed wiring boards 212a and 212b.

Although only a portion of printed wiring boards 212a and 212b are shown, it should be understood that printed wiring boards 212a and/or 212b may be electrically coupled to any suitable type of electrical circuit such as those described above with reference to FIGS. 1A and 1B.

Modifications, additions, or omissions may be made to electrical interconnection system 10, 100, or 200 without departing from the scope of the invention. The components of electrical interconnection system 10, 100, or 200 may be integrated or separated. For example, surface pads 18a and 18b may be integrally formed with conductors 30a and 30b, or they may be formed separately and coupled together in a later processing step. Moreover, the operations of electrical interconnection system 10, 100, or 200 may be performed by more, fewer, or other components. For example, surface pads 18a and 18b of the electrical interconnection system 10 of FIGS. 1A and 1B may be formed on a single side of tab 24 or may be formed on both sides of tab 24. As used in this document, “each” refers to each member of a set or each member of a subset of a set.

Although the present disclosure and its advantages have been described in detail, it should be understood that various changes, substitutions, and alterations can be made therein without departing from the spirit and scope of this disclosure as defined by the appended claims.

What is claimed is:

1. An electrical interconnection system comprising:
a pair of printed wiring boards that are each formed of a fiber reinforced resin material, the surface of one printed wiring board being formed on a tab of the printed wiring board and the surface of the other printed wiring board is formed in a slot of the other printed wiring board, each printed wiring board comprising:
a plurality of surface pads being formed of a layer of copper; and
a surface adjacent an outer edge of the printed wiring board on which the plurality of surface pads are configured, the surface of the printed wiring board operable to be placed adjacent to the surface of the other printed wiring board such that the electrical circuit coupled to the printed wiring board is electrically coupled to the electrical circuit of the other printed wiring board by contact of the plurality of surface pads of the printed wiring board with the plurality of surface pads of the other printed wiring board, the pair of printed wiring boards operable to be held together using one or more fasteners.

2. An electrical interconnection system comprising:
a pair of printed wiring boards that are each formed of a printed wiring board material, each printed wiring board comprising:
a plurality of surface pads; and
a surface adjacent an outer edge of the printed wiring board, the surface of the printed wiring board operable to be placed adjacent to the surface of the other printed wiring board such that an electrical circuit coupled to the printed wiring board is electrically coupled to another electrical circuit coupled to the other printed wiring board by contact of the plurality of surface pads of the printed wiring board with the plurality of surface pads of the other printed wiring board.

3. The electrical interconnection system of claim 2, wherein the surface of one printed wiring board is formed on tab of the printed wiring board and the surface of the other printed wiring board is formed in a slot of the other printed wiring board.

4. The electrical interconnection system of claim 2, further comprising tabs on both printed wiring boards, each tab comprising the surface.

5. The electrical interconnection system of claim 2, wherein at least one printed wiring board is integrally formed with the electrical circuit.

6. The electrical interconnection system of claim 2, further comprising one or more fasteners operable to hold the pair of printed wiring boards together.

7. The electrical interconnection system of claim 2, wherein the electrical circuit is selected from the group consisting of a printed wiring board (PWB), a flex circuit, a flex rigid circuit, a rigid circuit, a circuit card assembly (CCA), a cable bundle, and a plurality of wires.

8. The electrical interconnection system of claim 2, wherein at least one printed wiring board is coupled to one or more layers of flexible material comprising a polyimide material with a plurality of conductors electrically coupled to the plurality of surface pads.

9. The electrical interconnection system of claim 2, wherein the plurality of surface pads are formed of a layer of copper.

10. The electrical interconnection system of claim 2, wherein the plurality of surface pads are resilient for providing a spring-like force against the plurality of surface pads of the other printed wiring board.

11. the electrical interconnection system of claim 2, wherein the first layer of rigid material and the second layer of rigid material comprises a fiber reinforced resin material.

12. An electrical interconnection method comprising:
providing a pair of printed wiring boards that are each formed of a printed wiring board material, each printed wiring board comprising a plurality of surface pads configured on a surface adjacent an outer edge of the printed wiring board; and
placing the surface of the printed wiring board adjacent to the surface of the other printed wiring board such that the electrical circuit coupled to the printed wiring board is electrically coupled to the electrical circuit of the other printed wiring board by contact of the plurality of surface pads of the printed wiring board with the plurality of surface pads of the other printed wiring board.

13. The method of claim 12, wherein providing a pair of printed wiring boards comprises providing one printed wiring board with a tab comprising the surface and the other printed wiring board with a slot comprising the other surface.

14. The method of claim 12, wherein providing a pair of printed wiring boards comprises providing a pair of printed wiring boards that each have a tab comprising the surface.

15. The method of claim 12, wherein providing a pair of printed wiring boards comprises providing at least one of the printed wiring boards that is integrally formed with the electrical circuit.

16. The method of claim 12, further comprising holding the pair of printed wiring boards together using one or more fasteners.

17. The method of claim 12, wherein the electrical circuit is selected from the group consisting of a printed wiring board (PWB), a flex circuit, a flex rigid circuit, a rigid circuit, a circuit card assembly (CCA), a cable bundle, and a plurality of wires.

18. The method of claim 12, further comprising coupling at least one printed wiring board to one of more layers of flexible material comprising a polyimide material using a plurality of conductors that are electrically coupled to the plurality of surface pads.

19. The method of claim 12, wherein providing a pair of printed wiring boards comprises providing a pair of printed wiring boards that each have a plurality of surface pads formed of a layer copper.

20. The method of claim 12, wherein providing a pair of printed wiring boards that each has a plurality of surface pads comprises providing one printed wiring board with a plurality of resilient surface pads for providing a spring-like force against the plurality of surface pads of the other printed wiring board.

21. the method of claim 12, wherein providing a pair of printed wiring boards that each has a plurality of surface pads comprises providing a pair of printed wiring boards that each comprises a fiber reinforced resin material.
